(19) United States
(12) Patent Application Publication
(10) Pub. No.: US 2019/0185657 A1
(43) Pub. Date: Jun. 20, 2019

(54) SEALANT COMPOSITION AND SEALANT

(71) Applicant: SEKISUI POLYMATECH CO., LTD., Saitama-city, Saitama (JP)

(72) Inventor: Hitomi AIZAWA, Saitama-city, Saitama (JP)

(73) Assignee: SEKISUI POLYMATECH CO., LTD., Saitama-city, Saitama (JP)

(21) Appl. No.: 16/311,232

(22) PCT Filed: May 12, 2017
(86) PCT No.: PCT/JP2017/018122

§ 371 Date: Dec. 19, 2018

(30) Foreign Application Priority Data
Jul. 5, 2016 (JP) 2016-133708

(51) Int. Cl. C08L 53/02; C08F 20/20; C08F 2/46; C08G 59/28; C08G 59/50; H01L 23/29

(52) U.S. Cl. CPC C08L 53/02; C08F 20/20; C08F 2/46; H05K 3/28; C08G 59/50; H01L 23/293; C08L 2203/20; C08G 59/28

(57) ABSTRACT

Provided are a sealant that is affixed to an electronic device provided on an electronic substrate or the like or to an exposed metal portion to protect the electronic device or other adherend from moisture and the like and a sealant composition before being cured to become the sealant. The sealant and the sealant composition have form stability, flexibility, and adhesiveness.

The sealant composition contains, as essential components, a cured epoxy resin having a flexible backbone, a monofunctional (meth)acrylic ester monomer, a photo-radical polymerization initiator, and a styrene-based elastomer. The monofunctional (meth)acrylic ester monomer is curable by irradiation with light. The sealant composition has form stability and also has a flexibility such that a load measured when the sealant composition having a thickness of 1 mm is compressed by 25% with a cylindrical probe having a bottom end with a diameter of 10 mm is 0.19 to 3.2 N. The sealant is obtained by photocuring the sealant composition.

### TECHNICAL FIELD

The present invention relates to a sealant that is affixed to an electronic device provided on an electronic substrate or the like or to an exposed metal portion to protect the electronic device or other adherend from moisture, foreign matter, and the like and a sealant composition before becoming the sealant.

### BACKGROUND ART

Sealants made of epoxy resins are known. Such sealants are used to cover and protect electronic devices and the like in a manner that a liquid sealant composition made of an uncured epoxy resin is applied to a substrate or the like and then cured. A sealant of this type used by curing a liquid is advantageous in that because of being liquid, the sealant readily flows into gaps between electronic devices and is able to reliably cover the electronic devices but, on the other hand, is disadvantageous in that the sealant readily flows out of a desired area and thus may cover even a portion that should be exposed. Also, liquid sealant compositions disadvantageously have poor handling properties; for example, foreign matter is likely to adhere before curing, and the liquid sealant compositions may adhere to other members to stain them. To address these problems, solid sheet-like sealant compositions have been developed. For example, Japanese Unexamined Patent Application Publication No. 2012-087292 (PTL 1) describes a technique concerning a sheet-like sealant composition.

### CITATION LIST

### Patent Literature

PTL 1: Japanese Unexamined Patent Application Publication No. 2012-087292

### SUMMARY OF INVENTION

### Technical Problem

However, the technique described in Japanese Unexamined Patent Application Publication No. 2012-087292 (PTL 1) is disadvantageous in that it is necessary to heat and soften the sheet-like sealant composition in order to fill irregularities of electronic devices and the like on a substrate, and the heating takes a certain time, leading to time-consuming product manufacturing. In addition, since the viscosity of the sealant composition varies depending on the temperature, when the heating is insufficient, the temperature does not increase, and the sealant composition is insufficiently softened, which may result in failure to sufficiently fill the irregularities. On the other hand, when the viscosity is decreased by excessive heating, the sealant composition may flow out of a predetermined area.

The present invention has been made to solve the problems described above. Thus, an object of the present invention is to provide a sealant composition that is able to seal an adherend such as an electronic device without being heated and that has a desired flexibility after being completely cured.

Another object of the present invention is to provide a sealant having desired flexible properties.

### Solution to Problem

A sealant composition and a sealant for achieving the above objects according to the present invention are configured as follows.

Thus, provided is a sealant composition capable of protecting an adherend such as an electronic device from moisture, foreign matter, and the like by covering the adherend. The sealant composition contains, as essential components, a cured epoxy resin having a flexible backbone, a monofunctional (meth)acrylic ester monomer, a photo-radical polymerization initiator, and a styrene-based elastomer. The monofunctional (meth)acrylic ester monomer is curable by irradiation with light. The sealant composition has form stability and also has a flexibility such that a load measured when the sealant composition having a thickness of 1 mm is compressed by 25% with a cylindrical probe having a bottom end with a diameter of 10 mm is 0.19 to 3.2 N.

Because of containing a cured epoxy resin having a flexible backbone, a styrene-based elastomer, and a monofunctional (meth)acrylic ester monomer and having a flexibility such that a load measured when the sealant composition having a thickness of 1 mm is compressed by 25% with a cylindrical probe having a bottom end with a diameter of 10 mm is 0.19 to 3.2 N, the sealant composition has form stability and is also able to conform to the shape of an adherend such as an electronic device to seal the adherend.

Also, because of containing a monofunctional (meth)acrylic ester monomer and a photo-radical polymerization initiator, the monofunctional (meth)acrylic ester monomer undergoes a curing reaction in response to light and is cured, and thus a sealant having increased adhesion to an adherend can be provided.

The sealant composition may further contain a hydrophobic reinforcement powder in an amount of 5 to 50 parts by mass relative to 100 parts by mass of the epoxy resin so as to have form stability and also have a flexibility such that a load measured when the sealant composition having a thickness of 1 mm is compressed by 25% with a cylindrical probe having a bottom end with a diameter of 10 mm is 0.24 to 17.4 N.

Because the above sealant composition contains a hydrophobic reinforcement powder in an amount of 5 to 50 parts by mass relative to 100 parts by mass of the epoxy resin, the strength of the composition can be increased without increasing impact resilience. Also, because the above sealant composition has a flexibility such that a load measured when the sealant composition having a thickness of 1 mm is compressed by 25% with a cylindrical probe having a bottom end with a diameter of 10 mm is 0.24 to 17.4 N, handling properties can be dramatically improved in addition to having form stability. Meanwhile, because impact resilience is not increased even though the load is 0.24 to 17.4 N, the conformability to the shape of an adherend such as an electronic device is high, and spaces are less likely to occur.

Furthermore, because of containing a cured epoxy resin having a flexible backbone, a styrene-based elastomer, and a monofunctional (meth)acrylic ester monomer, a sealant obtained by curing the monofunctional (meth)acrylic ester monomer can be provided with desired flexible properties.

The monofunctional (meth)acrylic ester monomer may be constituted by a monofunctional alicyclic (meth)acrylic ester monomer and a monofunctional aliphatic (meth)acrylic ester monomer.

Because of containing a monofunctional alicyclic (meth)acrylic ester monomer, which monofunctional alicyclic (meth)acrylic ester monomer is liquid, the styrene-based elastomer can be dissolved. Also, the adhesiveness and moistureproofness of the sealant can be increased, and an adhesive transfer can be prevented when the sealant is peeled off an adherend.

Because of containing a monofunctional aliphatic (meth)acrylic ester monomer, which monofunctional aliphatic (meth)acrylic ester monomer is also liquid, the styrene-based elastomer can be dissolved. Also, the flexibility of the sealant can be improved, and the adhesiveness can be adjusted.

In the sealant composition, the monofunctional (meth)acrylic ester monomer may be contained in an amount of 175 to 400 parts by mass relative to 100 parts by mass of the cured epoxy resin.

Because the monofunctional (meth)acrylic ester monomer is contained in an amount of 175 to 400 parts by mass relative to 100 parts by mass of the cured epoxy resin in the sealant composition, the sealant composition can be excellent in form stability and conformability to irregularities, and a sealant having desired flexible properties can be provided by photocuring the monofunctional (meth)acrylic ester monomer.

In the sealant composition, the styrene-based elastomer may be contained in an amount of 75 to 200 parts by mass relative to 100 parts by mass of the cured epoxy resin.

Because the styrene-based elastomer is contained in an amount of 75 to 200 parts by mass relative to 100 parts by mass of the cured epoxy resin in the sealant composition, the sealant composition can be provided with form stability, and the viscosity of a liquid composition used as a raw material of the sealant composition can be suitable.

In the sealant composition, the weight percentage of the styrene-based elastomer relative to the total weight of the styrene-based elastomer and the monofunctional (meth)acrylic ester monomer may be 20 to 45 mass %.

Because the weight percentage of the styrene-based elastomer relative to the total weight of the styrene-based elastomer and the monofunctional (meth)acrylic ester monomer is 20 to 45 mass %, the sealant composition can be provided with form stability and flexibility, and a sealant having desired flexible properties can be provided by photocuring the monofunctional (meth)acrylic ester monomer.

The styrene-based elastomer may be a styrene-isobutylene-styrene block copolymer.

Because the styrene-based elastomer is a styrene-isobutylene-styrene block copolymer, weather resistance and heat resistance can be improved, and moisture permeability can be lowered.

The cured epoxy resin having a flexible backbone may be a cured epoxy resin that has two or more epoxy groups in one molecule and that includes, as a part of the molecule, at least one flexible backbone selected from a polyethylene glycol backbone, a polypropylene glycol backbone, a polyether backbone, a urethane backbone, a polybutadiene backbone, and a nitrile rubber backbone.

Because the cured epoxy resin having a flexible backbone is a cured epoxy resin that has two or more epoxy groups in one molecule and that includes, as a part of the molecule, at least one flexible backbone selected from a polyethylene glycol backbone, a polypropylene glycol backbone, a polyether backbone, a urethane backbone, a polybutadiene backbone, and a nitrile rubber backbone, the sealant composition can be provided with high flexibility.

Further provided is a sealant containing, as essential components, a cured epoxy resin having a flexible backbone, an acrylic resin, and a styrene-based elastomer, the acrylic resin being obtained by curing the monofunctional (meth)acrylic ester monomer in the above sealant composition. The sealant has desired flexible properties.

Because of containing, as essential components, a cured epoxy resin having a flexible backbone, an acrylic resin, and a styrene-based elastomer, the acrylic resin being obtained by curing the monofunctional (meth)acrylic ester monomer in the above sealant composition, and having desired flexibility, flexible properties can be provided that enable an electronic device or the like on a flexible substrate to be suitably sealed.

### Advantageous Effects of Invention

The sealant composition according to the present invention has form stability, does not run when covering an adherend such as an electronic device and allows the covering to be easily performed, and has excellent handling properties. The sealant composition can also be affixed to an adherend without being heated and is suitable for use for a heat-labile adherend. After sealing an adherend, the sealant composition can be photocured to enhance the adhesion to the adherend. Furthermore, a sealant obtained by photocuring is provided with desired flexible properties.

The sealant according to the present invention has flexible properties and can be suitably applied also to an adherend such as a flexible substrate.

### DESCRIPTION OF EMBODIMENTS

### First Embodiment

<Sealant Composition>

The present invention will be described in more detail with reference to embodiments. A sealant composition according to the present invention is affixed, for example, to an electronic substrate having an electronic device disposed thereon, pressed to cover and come into close contact with the electronic device, and then cured by irradiation with light to provide a sealant that has increased adhesion to the electronic device and protects the electronic device from moisture, foreign matter, and the like.

The sealant composition contains, as essential components, a cured epoxy resin having a flexible backbone, a monofunctional (meth)acrylic ester monomer, a photo-radical polymerization initiator, and a styrene-based elastomer. The essential components of the sealant composition will now be described.

Cured Epoxy Resin:

The epoxy resin exists in the form of a cured resin in the sealant composition, and the cured resin is obtained by mixing a base epoxy resin with a curing agent and heat-setting the mixture.

The base epoxy resin (hereinafter referred to simply as the “base resin”) used has two or more epoxy groups in one molecule and includes, as a part of the molecule, a flexible backbone such as a polyethylene glycol backbone, a polypropylene glycol backbone, a polyether backbone, a urethane backbone, a polybutadiene backbone, or a nitrile rubber backbone. Thus, when the epoxy resin is cured, its flexibility is increased.

More specifically, the base epoxy resin having a flexible backbone may be “an epoxy resin compound having an aromatic dihydroxy compound and a polyalkylene glycol linked together and epoxy end groups” obtained by reacting an aromatic dihydroxy compound, such as bisphenol A, with an alkylene oxide, such as ethylene oxide or propylene oxide, to synthesize a compound having a polyalkylene glycol backbone and further epoxidizing the ends of the compound having a polyalkylene glycol backbone; “an epoxy resin compound having an alkanediol or a polyalkylene glycol and an aromatic dihydroxy compound linked together and epoxy end groups” obtained by epoxidizing an alkanediol, such as propanediol or butanediol, or a polyalkylene glycol, such as diethylene glycol or polypropylene glycol, further reacting the resultant with an aromatic dihydroxy compound, such as bisphenol A, and epoxidizing the product; “an epoxy resin compound having an aliphatic backbone, an aromatic backbone, an alkanediol, or a polyalkylene glycol and an aromatic dihydroxy compound linked together and epoxy end groups” obtained by divinyl-etherifying an aliphatic or aromatic hydrocarbon compound, an alkanediol, such as propanediol or butanediol, or a polyalkylene glycol, such as diethylene glycol or polypropylene glycol, further reacting the resultant with an aromatic dihydroxy compound, such as bisphenol A, and epoxidizing the product; “an epoxy resin compound having an aliphatic backbone” obtained by reacting an aliphatic dicarboxylic acid, such as dimer acid or sebacic acid, with a bisphenol A epoxy resin or other epoxidizing agent; or “an epoxy resin compound having a polyalkylene glycol structure having epoxy end groups” obtained by epoxidizing the ends of a polyalkylene glycol such as propylene oxide.

Although every base resin may contain a component not having a flexible backbone, such as a bisphenol A epoxy resin or a bisphenol F epoxy resin, the percentage of such a component in the entire base resin is preferably 50% or less, and in particular the percentage of an epoxy resin component having a flexible backbone is preferably higher, more preferably 100%.

Such a base resin can provide a mixture in which the base resin and the (meth)acrylic ester monomer are compatible with each other, and photoreaction can be used as the curing reaction for obtaining the sealant composition. However, if the transparency of the sealant composition is significantly impaired, the curing properties at a deep part may be impaired, and thus the transparency is preferably higher.

As a curing agent for the epoxy resin, for example, a common amine-based curing agent, an acid-anhydride-based curing agent, a phenol-based curing agent, a polymercaptan-based curing agent, a polyaminoamide-based curing agent, an isocyanate, or a blocked isocyanate can be used. These curing agents may be used alone or as a mixture of two or more. The incorporation ratio of these curing agents to the base resin may be the same as in the case where these curing agents are commonly used.

Among the above curing agents for the epoxy resin, the amine-based curing agent is preferably used. This is because the amine-based curing agent is compatible with the styrene-based elastomer and the (meth)acrylic ester monomer and can provide a homogeneous cured resin.

Specific examples of the amine-based curing agent include aliphatic amines, polyether polyamines, alicyclic amines, and aromatic amines. Examples of aliphatic amines include ethylenediamine, 1,3-diaminopropane, 1,4-diaminopropane, hexamethylenediamine, 2,5-dimethylhexamethylenediamine, trimethylhexamethylenediamine, diethylenetriamine, iminobispropylamine, bis(hexamethylene)triamine, triethylenetetramine, tetraethylenepentamine, pentaethylenehexamine, N-hydroxyethylethylenediamine, and tetra(hydroxyethyl)ethylenediamine. Examples of polyether polyamines include triethylene glycol diamine, tetraethylene glycol diamine, diethylene glycol bis(propylamine), polyoxypropylenediamine, and polyoxypropylenetriamine. Examples of alicyclic amines include isophoronediamine, methacenediamine, N-aminoethylpiperazine, bis(4-amino-3-methyldicyclohexyl)methane, bis(aminomethyl)cyclohexane, 3,9-bis(3-aminopropyl)2,4,8,10-tetraoxaspiro(5,5)undecane, and norbornenediamine. Examples of aromatic amines include tetrachloro-p-xylenediamine, m-xylenediamine, p-xylenediamine, m-phenylenediamine, o-phenylenediamine, p-phenylenediamine, 2,4-diaminoanisole, 2,4-toluenediamine, 2,4-diaminodiphenylmethane, 4,4′-diaminodiphenylmethane, 4,4′-diamino-1,2-diphenylethane, 2,4-diaminodiphenylsulfone, 4,4′-diaminodiphenylsulfone, m-aminophenol, m-aminobenzylamine, benzyldimethylamine, 2-dimethylaminomethylphenol, triethanolamine, methylbenzylamine, α-(m-aminophenyl)ethylamine, α-(p-aminophenyl)ethylamine, diaminodiethyldimethyldiphenylmethane, and α,α′-bis(4-aminophenyl)-p-diisopropylbenzene.

Among the above specific examples, aliphatic amines, polyether polyamines, and alicyclic amines are preferably used in view of the compatibility with other raw materials and the flexibility of the sealant.

The cured epoxy resin obtained by heat-setting a base epoxy resin and a curing agent can impart form stability to the sealant composition and the sealant. The cured epoxy resin, because of having a flexible backbone, also contributes to increasing the flexibility, low moisture permeability, and waterproofness of the sealant composition and the sealant.

The content of the cured epoxy resin in the sealant composition or the sealant is preferably 15 to 27 mass %. When the content is less than 15 mass %, the sealant composition may fail to have desired form stability. On the other hand, when the content is more than 27 mass %, the sealant may be too hard.

Monofunctional (Meth)Acrylic Ester Monomer:

The monofunctional (meth)acrylic ester monomer is a component for fixing the sealant composition to an electronic device or a substrate and providing waterproofness and other properties. The monofunctional (meth)acrylic ester monomer is also a component for dissolving the styrene-based elastomer and homogeneously mixing the sealant composition. This monofunctional (meth)acrylic ester monomer is cured through a photo-radical reaction to become an acrylic resin (cured resin). The reason why the monofunctional (meth)acrylic ester monomer among (meth)acrylic ester monomers is used is to obtain a flexible sealant.

Examples of the monofunctional (meth)acrylic ester monomer include aliphatic (meth)acrylic ester monomers, alicyclic (meth)acrylic ester monomers, ether (meth)acrylic ester monomers, cyclic ether (meth)acrylic ester monomers, hydroxyl-containing (meth)acrylic ester monomers, aromatic (meth)acrylic ester monomers, and carboxyl-containing (meth)acrylic ester monomers. Among these, a monofunctional alicyclic (meth)acrylic ester monomer and a monofunctional aliphatic (meth)acrylic ester monomer are preferably used in combination.

By incorporating a monofunctional alicyclic (meth)acrylic ester monomer, the adhesive strength of the sealant can be increased, while an adhesive transfer is less likely to occur when the sealant is peeled off. Also, the sealant is advantageously strengthened to have increased tensile strength. In addition, increasing the percentage of this component can increase moistureproofness and transparency.

Specific examples of the monofunctional alicyclic (meth)acrylic ester monomer include isobornyl acrylate, cyclohexyl acrylate, dicyclopentanyl acrylate, 3,3,5-trimethylcyclohexyl acrylate, and 4-tert-butylcyclohexyl acrylate.

On the other hand, by incorporating a monofunctional aliphatic (meth)acrylic ester monomer in the sealant, the flexibility of the sealant can be increased to significantly improve elongation at break.

Specific examples of the monofunctional aliphatic (meth)acrylic ester monomer include aliphatic ether (meth)acrylic ester monomers such as ethoxydiethylene glycol acrylate, 2-ethylhexyl diglycol acrylate, butoxyethyl acrylate, phenoxyethyl acrylate, and nonylphenol-ethylene oxide-modified acrylate; and aliphatic hydrocarbon (meth)acrylic ester monomers such as lauryl acrylate, stearyl acrylate, isostearyl acrylate, decyl acrylate, and isodecyl acrylate.

The total amount of the monofunctional alicyclic and monofunctional aliphatic (meth)acrylic ester monomers incorporated may be 55 to 80 mass % relative to the total weight of these (meth)acrylic ester monomers plus the styrene-based elastomer. The weight ratio of the monofunctional alicyclic (meth)acrylic ester monomer to the monofunctional aliphatic (meth)acrylic ester monomer may be 3:2 to 1:4.

When the weight of the monofunctional aliphatic (meth)acrylic ester monomer is more than four times the weight of the monofunctional alicyclic (meth)acrylic ester monomer, an adhesive transfer may occur when the sealant is peeled off, and adhesive strength and moistureproofness may be insufficient. On the other hand, when it is less than two thirds, the sealant is likely to be hard, and furthermore, the adhesion may excessively increase with time, leading to difficulty in peeling off. If the weight ratio of the monofunctional alicyclic (meth)acrylic ester monomer to the monofunctional aliphatic (meth)acrylic ester monomer is in the range of 3:2 to 1:4, a sealant that has a high elongation at break and is easily peeled off can be provided.

The monofunctional (meth)acrylic ester monomer is essential as described above, and a bi- or more functional (meth)acrylic ester monomer can also be used in a small amount for the purpose of, for example, hardness adjustment and surface tackiness reduction.

The bi- or more functional (meth)acrylic ester monomer is preferably contained in an amount of 15 mass % or less relative to the amount of the monofunctional (meth)acrylic ester monomer. When the amount of the bi- or more functional (meth)acrylic ester monomer is more than 15 mass %, the flexible properties of the sealant may be lost.

Preferably, the (meth)acrylic ester monomer is contained as much as possible in the sealant composition or the sealant. Specifically, the (meth)acrylic ester monomer is preferably contained in an amount of 44 to 64 mass % in the sealant composition or the sealant. When the amount of the (meth)acrylic ester monomer is less than 44 mass %, desired adhesive strength may not be provided, and the sealant may be hard if the amount of the styrene-based elastomer added is also small. On the other hand, when the amount of the (meth)acrylic ester monomer is more than 64 mass %, the form stability of the sealant composition may be impaired.

The (meth)acrylic ester monomer is preferably incorporated in an amount of 175 to 400 parts by mass relative to 100 parts by mass of the epoxy resin. When the amount of the (meth)acrylic ester monomer is less than 175 parts by mass, the sealant may be hard and hinder the deformation of a flexible substrate when applied thereto. Also, the hardness of the sealant composition may be increased, making it difficult to fill irregularities of an adherend such as a circuit element. On the other hand, when the amount of the (meth)acrylic ester monomer is more than 400 parts by mass, the form stability of the sealant composition may be impaired.

Styrene-Based Elastomer:

The styrene-based elastomer is a component that imparts rubber elasticity (flexibility) to the sealant together with the monofunctional (meth)acrylic ester monomer and has the effect of increasing the form stability of the sealant composition. Due to having the effect of imparting form stability, the content of the cured epoxy resin can be reduced. The reduction of the content of the cured epoxy resin contributes to increasing the flexibility of the sealant. Furthermore, the styrene-based elastomer has the effect of improving the mechanical strength of the sealant and increasing the expansion and contraction properties of the sealant.

The styrene-based elastomer alone is solid and thus has no adhesiveness at normal temperature, but when in the form of a solution in the monofunctional (meth)acrylic ester monomer, the styrene-based elastomer can be homogeneously dispersed in the sealant composition and the sealant.

The styrene-based elastomer preferably has a hardness, A hardness defined in JIS K6253, of not higher than A70. This is because a hardness of not higher than A70 can effectively impart flexibility to the sealant.

Among styrene-based elastomers, a styrene-isobutylene-styrene block copolymer is preferably used. This is because the styrene-isobutylene-styrene block copolymer has an isobutylene backbone, and thus has high weather resistance and high heat resistance and can also lower moisture permeability.

The amount of the styrene-based elastomer incorporated is preferably 75 to 200 parts by mass, more preferably 75 to 180 parts by mass, relative to 100 parts by mass of the epoxy resin. When the amount of the styrene-based elastomer is less than 75 parts by mass, the form stability of the sealant composition may be slightly impaired if the amount of the monofunctional (meth)acrylic ester monomer is relatively large, and the sealant may be hard if the amount of the monofunctional (meth)acrylic ester monomer is relatively small. On the other hand, when the amount of the styrene-based elastomer is more than 200 parts by mass, a liquid composition from which the sealant composition is made may have a high viscosity and may be difficult to apply. Thus, the amount of the styrene-based elastomer is preferably 180 parts by mass or less.

The amount of the styrene-based elastomer incorporated may be 20 to 45 mass % relative to the total weight of the styrene-based elastomer plus the monofunctional (meth)acrylic ester monomer. When the amount of the styrene-based elastomer incorporated is more than 45 mass %, the liquid composition may have a high viscosity and may be difficult to apply. On the other hand, when the amount of the styrene-based elastomer incorporated is less than 20 mass %, the mechanical strength may be weak.

Photo-Radical Polymerization Initiator:

The photo-radical polymerization initiator causes the monofunctional (meth)acrylic ester monomer to undergo photoreaction to be cured. Specifically, photopolymerization initiators such as benzophenone-based, thioxanthone-based, acetophenone-based, and acylphosphine-based initiators can be used. The amount of the photo-radical polymerization initiator incorporated is preferably 0.1 to 10 parts by weight, more preferably 1 to 8 parts by weight, relative to 100 parts by weight of the total amount of the various (meth)acrylic ester monomers.

Other Components:

Various additives can be appropriately incorporated without departing from the spirit of the present invention. Examples include silane coupling agents, polymerization inhibitors, antifoaming agents, light stabilizers, antioxidants, antistatic agents, and fillers.

<Production of Sealant Composition>

To produce the sealant composition, a liquid composition that is a raw material containing, as essential components, a base epoxy resin before becoming a cured epoxy resin, a curing agent, a monofunctional (meth)acrylic ester monomer, a photo-radical polymerization initiator, and a styrene-based elastomer (hereinafter referred to simply as a “liquid composition”) is provided. The liquid composition is then heated to cause a thermosetting reaction between the base epoxy resin and the curing agent in the components, thus providing the sealant composition.

The hardness of the sealant composition can be such that the load measured when the sealant composition having a thickness of 1 mm is compressed by 25%, i.e., compressed to 0.75 mm with a cylindrical metal probe having an end with a diameter of 10 mm is 0.19 to 3.2 N. If the load is 3.2 N or less, the sealant composition, when pressed to come into close contact with an electronic substrate, can advantageously flexibly conform to irregularities of an electronic device under a small load that does not impose an excessive stress on the electronic substrate. Therefore, the electronic substrate and the sealant can be brought into close contact with no gaps to achieve secure sealing without applying a load on the electronic substrate. If the load is 0.19 N or more, the sealant composition can be provided with form stability and has good handling properties.

The reason why the above measurement method is employed is that it is difficult to determine a desired hardness range, for example, with the type OO hardness defined in ASTM D2240 or the penetration measurement defined in JIS K2220 or JIS K2207. Load values obtained by the above measurement method are unlikely to depend on the test piece thickness in principle but are known to have a slight thickness dependency. Specifically, in the case of a sample having a thickness of 2 mm, the load is 0.15 to 2.9 N; the load tends to decrease as the thickness increases.

The sealant composition thus obtained, in which the epoxy resin, the (meth)acrylic acid monomer, and the styrene-based elastomer are homogeneously mixed without being separated from one another, is flexible and has high toughness. The sealant composition also has stickiness and can be cured by light.

For example, its tensile elongation at break and tensile strength at break are higher than those of sealant compositions with no styrene-based elastomer added. In the case where an elastomer powder insoluble in the epoxy resin and the (meth)acrylic acid monomer is only added, the tensile strength at break is slightly poor although the addition of the elastomer provides a slight flexibility.

<Sealant>

The above sealant composition is affixed to an electronic device provided on an electronic substrate or the like or to an exposed metal portion to cover the electronic device or other adherend and then irradiated with light to cure the monofunctional (meth)acrylic ester monomer through a radical photopolymerization reaction, thus forming a sealant. The sealant formed by irradiating the sealant composition with light is also a flexible rubber-like elastic body. The storage modulus E′ of the sealant, as measured with a dynamic viscoelasticity meter, is in the range of 0.4 to 4.1 MPa. When the storage modulus E′ is less than 0.4 MPa, strength may be low, and when the storage modulus E′ is more than 4.1 MPa, flexible properties that enable mounting on a flexible substrate may be impaired.

This sealant has an adhesive strength derived from the (meth)acrylic ester monomer and is able to come into close contact with an electronic device or the like to prevent the entry of foreign matter and moisture. Also, since the monofunctional (meth)acrylic ester monomer left unreacted in the sealant composition is cured while being affixed to an adherend so as to be present as an acrylic resin in the sealant, the adhesion to the adherend is high.

The sealant may be provided with a reinforcement layer. The reinforcement layer may be, for example, a composition that is of the same type as the sealant composition and has an adjusted hardness, a urethane film or other resin film, or a mesh. Such a reinforcement layer, if stacked, is provided on the surface opposite to the surface that will come into close contact with an adherend such as an electronic substrate.

The hardness of the composition of the same type as the sealant composition may be adjusted, for example, by increasing the percentage of the epoxy resin contained in the components or incorporating a bi- or more functional (meth)acrylic ester monomer in a large amount.

The reinforcement layer may be provided, for example, by sequentially applying a liquid composition to become the sealant composition and a liquid composition to become the reinforcement layer to obtain a sheet or by stacking the sealant composition and a reinforcement film or the like on each other and bonding the sealant composition to the reinforcement film when the sealant composition is cured.

As described above, the monofunctional (meth)acrylic ester monomer, which is a component of the sealant composition, is a radically polymerizable monomer and incorporated as a compound to be photocured. The base epoxy resin and the curing agent are incorporated as a compound to be cured by heating. Thus, since the components that undergo different curing reactions are incorporated, a liquid composition that is a homogeneous mixture in which both the components are in an unreacted state can be first prepared, the sealant composition having form stability can then be prepared by curing the base epoxy resin and the curing agent by heating, and the operation of covering an electronic device or an electronic substrate with the sealant composition can be easily performed. After the adherend is covered, stickiness to the adherend can be converted into adhesiveness by curing the monofunctional (meth)acrylic ester monomer by irradiation with light.

That is to say, since the thermosetting compound and the photocurable compound that are cured through different independent curing reactions are contained, form stability and adhesiveness can be achieved at different stages. A combination of a thermal radical polymerization and an epoxy curing reaction by irradiation with light, where the curing with light and the curing with heat are reversed, is also possible. Since the latter reaction is radical photopolymerization, an electronic device or an electronic substrate can be sealed without being exposed to a high temperature, and thus this combination is suitable for sealing a device having low heat resistance.

There is also known a method in which such an independent different curing component is not incorporated, and, for example, one curing component such as an epoxy resin or a (meth)acrylic ester monomer is cured stepwise, for example, in such a manner that the reaction is stopped in a semi-cured state (B-staging). However, the epoxy resin in the B-stage is difficult to flexibilize and, if not heated, may fail to flexibly conform to irregularities of an electronic device on an electronic substrate. Also, since the reaction of the (meth)acrylic ester monomer is a radical reaction, it is difficult to stop the reaction in the semi-cured state. Also from this viewpoint, it is advantageous to incorporate two independent curing components.

### Second Embodiment

<Sealant Composition>

A sealant composition according to a second embodiment is constituted by the sealant composition described in the first embodiment and a hydrophobic reinforcement powder. Components other than the hydrophobic reinforcement powder are the same as the components described in the first embodiment, and thus descriptions thereof will be omitted.

Hydrophobic Reinforcement Powder:

The hydrophobic reinforcement powder is a component added to improve the handling properties of the sealant composition. The hydrophobic reinforcement powder is preferably added in an amount of 5 to 50 parts by mass relative to 100 parts by mass of the epoxy resin because the handling properties of the sealant composition are dramatically improved. When the amount of the hydrophobic reinforcement powder is less than 5 parts by mass, the handling properties are less improved, whereas when added in an amount of more than 50 parts by mass, ultraviolet transmission may be impaired, making the sealant composition hard to cure. Also, the proportion of the resin component is excessively small, and the sealant composition and the sealant may be too hard.

The hydrophobic reinforcement powder may be a powder that is hydrophobic and has a relatively small particle size. Having hydrophobic characteristics can reduce the likelihood that moisture is absorbed and enhance the functionality of the sealant. The primary particles of the powder preferably have an average particle size of less than 1 μm. This is because when the average particle size is 1 μm or more, the reinforcing effect is not readily exhibited, and it is difficult to sufficiently improve the handling properties. Also, since it is necessary to photocure the sealant composition to provide a sealant, the powder is preferably a transparent powder that does not absorb light for curing. Furthermore, to increase the insulation between electronic devices and wires, the powder is preferably a powder with high-insulation properties. Examples of materials of such a hydrophobic reinforcement powder include hydrophobic silica powder, polysilsesquioxane powder, silicone powder, hydrophobic cellulose powder, metal oxide powder, and nanoclay powder.

The hardness of the sealant composition containing a hydrophobic reinforcement powder can be such that the load measured when the sealant composition having a thickness of 1 mm is compressed by 25%, i.e., compressed to 0.75 mm with a cylindrical metal probe having an end with a diameter of 10 mm is 0.24 to 17.4 N. If the load is 0.24 N or more, excellent handling properties can be provided in addition to form stability. If the load is more than 3.2 N but not more than 17.4 N, the impact resilience of the sealant composition is not increased, and thus the sealant composition, when pressed to come into close contact with an electronic substrate, can conform to irregularities of an electronic device. Therefore, the electronic substrate and the sealant can be brought into close contact with no gaps to achieve secure sealing without applying a great load on the electronic substrate.

Also regarding the sealant composition containing a hydrophobic reinforcement powder, the above load values have a slight thickness dependency. In the case of the sealant composition whose load value is in the range of 0.24 to 17.4 N when the thickness is 1 mm, the load value is in the range of 0.12 to 10.7 N when the thickness is 2 mm; the load value decreases as the thickness increases.

Here, the difference between the sealant composition according to the present invention containing a hydrophobic reinforcement powder and the sealant composition according to the present invention containing no hydrophobic reinforcement powder will be described. The sealant composition containing no hydrophobic reinforcement powder has no risk of, for example, running and has form stability such that the handling properties of conventional liquid sealants are improved. However, even though having form stability, if flexibility is very high, workability is sometimes not improved so much during the production process thereof or when attached to seal an electronic device or the like, and there remains room for improvement in the handling properties.

From the viewpoint of improvement in the handling properties of the sealant composition containing no hydrophobic reinforcement powder, when the crosslink density of the resin component is increased, for example, by increasing the percentage of the epoxy resin without adding a hydrophobic reinforcement powder to achieve a hardness such that the above-described load is more than 3.2 N, the increase in crosslink density results in increased impact resilience, which makes it difficult to flexibly conform to irregularities of an electronic device and increases the likelihood that spaces are formed at the corners of recesses. In addition, the relative decrease in the content of the (meth)acrylic ester monomer, which is a secondary curing component, due to the increase in the content of the epoxy resin may also impair the adhesive strength of the sealant.

On the other hand, the sealant composition having a hardness increased by adding a hydrophobic reinforcement powder advantageously has increased strength due to the weak interaction of the hydrophobic reinforcement powder. This interaction, unlike chemical bonding, does not increase the impact resilience of the sealant composition, and thus the conformability of the sealant composition to irregularities of an electronic instrument is never to be impaired when the load is more than 3.2 N but not more than 17.4 N. In this case, the ratio of the (meth)acrylic ester monomer to the epoxy resin or thermoplastic elastomer does not change, and thus a sealant having desired adhesive strength can be provided.

<Production of Sealant Composition>

To produce the sealant composition described in the second embodiment, a liquid composition is provided that is a raw material containing, as essential components, a base epoxy resin before becoming a cured epoxy resin, a curing agent, a monofunctional (meth)acrylic ester monomer, a photo-radical polymerization initiator, a styrene-based elastomer, and a hydrophobic reinforcement powder. The liquid composition is then heated to cause a thermosetting reaction between the base epoxy resin and the curing agent in the components, thus producing the sealant composition.

The sealant composition thus obtained, in which the epoxy resin, the (meth)acrylic ester monomer, and the styrene-based elastomer are homogeneously mixed without being separated from one another, is flexible and has high toughness. The sealant composition also has stickiness and can be cured by light. For example, its tensile elongation at break and tensile strength at break are higher than those of sealant compositions with no styrene-based elastomer added. In the case where an elastomer powder insoluble in the epoxy resin and the (meth)acrylic ester monomer is only added, the tensile strength at break is slightly poor although the addition of the elastomer provides a slight flexibility. By contrast, the above sealant composition also has a high tensile strength at break. As compared to the case where no hydrophobic reinforcement powder is added, the sealant composition is slightly hard but has remarkably improved handling properties, comparable conformability to irregularities, and high adhesiveness.

<Sealant>

The sealant composition containing a hydrophobic reinforcement powder is affixed to an electronic device provided on an electronic substrate or the like or to an exposed metal portion to cover the electronic device or other adherend, and then irradiated with light to cure the monofunctional (meth)acrylic ester monomer through a radical photopolymerization reaction, thus forming a sealant. The sealant thus obtained is also a flexible rubber-like elastic body. The storage modulus E′ of the sealant, as measured with a dynamic viscoelasticity meter, will probably be in the range of 0.4 to 6.1 MPa. This is because when the storage modulus E′ is less than 0.4 MPa, strength may be low; when the storage modulus E′ is more than 4.1 MPa and is 6.1 MPa, the sealant will probably be rated at least “Δ” and not “×” in the evaluation of flexible properties described below; and when the storage modulus E′ is more than 6.1 MPa, flexible properties that enable mounting on a flexible substrate may probably be impaired.

The embodiments described above are merely illustrative examples of the present invention. Without departing from the gist of the present invention, the embodiments can be modified, and the known art can be added to or combined with the embodiments. Such technical features are also included in the scope of the present invention.

### EXAMPLES

The present invention will now be described in more detail with reference to an experimental example.

Sealant compositions and sealants of Sample 1 to Sample 16 below were prepared.

<Preparation of Samples>

Sample 1:

A homogeneous liquid composition was obtained by mixing 72 parts by mass of a bifunctional epoxy resin compound (“EP-4000S” manufactured by ADEKA Corporation), serving as a base epoxy resin, that has a flexible backbone and has, in its molecule, two epoxy groups and bisphenol A with polyalkylene oxide, which is the flexible backbone, added (hereinafter referred to as a “base resin 1”), 28 parts by mass of a polyamine (“EH-4357S” manufactured by ADEKA Corporation), serving as a curing agent for the epoxy resin, 52.5 parts by mass of lauryl acrylate, which is a monofunctional aliphatic (meth)acrylic ester monomer, 52.5 parts by mass of isobornyl acrylate, which is a monofunctional alicyclic (meth)acrylic ester monomer, 45 parts by mass of a styrene-based elastomer, and 5.3 parts by mass of 2-hydroxy-2-methyl-1-phenyl-propan-1-one, serving as a photo-radical polymerization initiator.

Next, the liquid composition was sandwiched between a pair of release films so as to be 1.0 mm thick and heated at 120° C. for 30 minutes in this state, thus curing the base epoxy resin and the curing agent to prepare a sheet-like sealant composition. Thus, a sealant composition of Sample 1 was obtained.

The release film on one side of the sealant composition was then peeled off, and the exposed surface of the sealant composition was affixed to a urethane sheet having a thickness of 0.1 mm, after which a flat pushing plate was pressed thereagainst at a pressure of 0.3 MPa for 5 seconds. Thereafter, the sealant composition was irradiated with ultraviolet light under the conditions of an illuminance of 600 mW/cm² and a total light quantity of 5000 mJ/cm² to prepare a sealant. Thus, a sealant of Sample 1 was obtained.

TABLE 1

| | | Sample | Sample | Sample | Sample | Sample | Sample | Sample | Sample | Sample |
|---|---|---|---|---|---|---|---|---|---|---|
| | | 1 | 2 | 3 | 4 | 5 | 6 | 7 | 8 | 9 |
| (A) Epoxy resin | Base resin 1 | 72 | 72 | 72 | 72 | 72 | 72 | 72 | 72 | 72 |
| | Base resin 2 | — | — | — | — | — | — | — | — | — |
| | Curing agent | 28 | 28 | 28 | 28 | 28 | 28 | 28 | 28 | 28 |
| (B) Monofunctional | Alicyclic | 52.5 | 70 | 87.5 | 100 | 105 | 140 | 175 | 200 | 245 |
| acrylic monomer | Aliphatic | 52.5 | 70 | 87.5 | 100 | 105 | 140 | 175 | 200 | 245 |
| (C) Styrene-based elastomer | | 45 | 60 | 75 | 86 | 90 | 120 | 150 | 170 | 210 |
| Photo-radical polymerization | | 5.3 | 7.0 | 8.8 | 10.0 | 10.5 | 14.0 | 17.5 | 20.0 | 24.5 |
| initiator | | | | | | | | | | |
| Incorporation ratio | Percentage | 40 | 33 | 29 | 26 | 25 | 20 | 17 | 15 | 13 |
| of resins | (%) of (A) | | | | | | | | | |
| | Percentage | 42 | 47 | 50 | 52 | 53 | 56 | 58 | 60 | 61 |
| | (%) of (B) | | | | | | | | | |
| | Percentage | 18 | 20 | 21 | 22 | 23 | 24 | 25 | 25 | 26 |
| | (%) of (C) | | | | | | | | | |
| Evaluations of | Load (N) | 7.1 | 3.5 | 3.2 | 3.1 | 3.1 | 1.0 | 0.72 | 0.70 | — |
| sealant | Form stability | ∘ | ∘ | ∘ | ∘ | ∘ | ∘ | ∘ | Δ | x |
| composition | Conformability | x | x | ∘ | ∘ | ∘ | ∘ | ∘ | ∘ | — |
| | to irregularities | | | | | | | | | |
| Evaluations of | Storage | 3.2 | 0.9 | 0.7 | 0.7 | 0.7 | 0.7 | 0.6 | 0.6 | — |
| sealant | modulus E′ | | | | | | | | | |
| | (MPa) | | | | | | | | | |
| | Flexible | Δ | ∘ | ∘ | ∘ | ∘ | ∘ | ∘ | ∘ | — |
| | properties | | | | | | | | | |

| | | Sample | Sample | Sample | Sample | Sample | Sample | Sample |
|---|---|---|---|---|---|---|---|---|
| | | 10 | 11 | 12 | 13 | 14 | 15 | 16 |
| (A) Epoxy resin | Base resin 1 | 72 | 72 | 72 | 72 | 72 | — | 36 |
| | Base resin 2 | — | — | — | — | — | 62 | 31 |
| | Curing agent | 28 | 28 | 28 | 28 | 28 | 38 | 33 |
| (B) Monofunctional | Alicyclic | 120 | 110 | 160 | 64 | 200 | 140 | 140 |
| acrylic monomer | Aliphatic | 120 | 110 | 160 | 64 | 200 | 140 | 140 |
| (C) Styrene-based elastomer | | 160 | 180 | 80 | 0 | 0 | 120 | 120 |
| Photo-radical polymerization | | 12.0 | 11.0 | 16.0 | 6.4 | 20.0 | 14.0 | 14.0 |
| initiator | | | | | | | | |
| Incorporation ratio | Percentage | 20 | 20 | 20 | 44 | 20 | 9 | 15 |
| of resins | (%) of (A) | | | | | | | |
| | Percentage | 48 | 44 | 64 | 56 | 80 | 64 | 60 |
| | (%) of (B) | | | | | | | |
| | Percentage | 32 | 36 | 16 | 0 | 0 | 27 | 26 |
| | (%) of (C) | | | | | | | |
| Evaluations of | Load (N) | 3.1 | 3.2 | 0.19 | 2.0 | — | 0.59 | 0.78 |
| sealant | Form stability | ∘ | ∘ | Δ | ∘ | x | ∘ | ∘ |
| composition | Conformability | ∘ | Δ | ∘ | ∘ | — | ∘ | ∘ |
| | to irregularities | | | | | | | |
| Evaluations of | Storage | 0.8 | 1.2 | 0.4 | 0.4 | — | 8.4 | 4.1 |
| sealant | modulus E′ | | | | | | | |
| | (MPa) | | | | | | | |
| | Flexible | ∘ | ∘ | ∘ | x | — | x | Δ |
| | properties | | | | | | | |

Sample 2 to Sample 12:

Sealant compositions and sealants of Sample 2 to Sample 12 were prepared in the same manner as in Sample 1 except that the same raw materials as in Sample 1 were used but the incorporation amounts thereof were changed as shown in Table 1.

Samples 13, 14:

Regarding Sample 13 and Sample 14, sealant compositions and sealants of Sample 13 and Sample 14 were prepared in the same manner as in Sample 1 except that the styrene-based elastomer was not incorporated and that the incorporation amounts of other raw materials were changed as shown in Table 1.

Samples 15, 16:

Regarding Sample 15, a sealant composition and a sealant of Sample 15 were prepared in the same manner as in Sample 1 except that the base epoxy resin 1 was replaced with a 1:1 mixture of bisphenol A epoxy resin and bisphenol F epoxy resin not having a flexible backbone (hereinafter referred to as a “base resin 2”) and that the incorporation amounts of other raw materials were changed as shown in Table 1.

Regarding Sample 16, a sealant composition and a sealant of Sample 16 were prepared in the same manner as in Sample 15 except that “base resin 1+curing agent” and “base resin 2+curing agent” were mixed at 1:1 and used.

Sample 17 to Sample 20:

Sealant compositions and sealants of Sample 17 to Sample 20 were prepared in the same manner as in Sample 1 except that the same raw materials as in Sample 1 were used but a hydrophobic reinforcement powder was further added, and the incorporation amounts thereof were changed as shown in Table 2. As the hydrophobic reinforcement powder, a fumed silica (primary particle size, 12 nm; specific surface area, 140 m²/g) having a surface trimethylsilylated by hydrophobization was used in Sample 17 to Sample 19, and a silicone rubber powder (spherical; average particle size, 0.8 μm) coated with a silicone resin was used in Sample 20.

TABLE 2

| | | Sample | Sample | Sample | Sample |
|---|---|---|---|---|---|
| | | 17 | 18 | 19 | 20 |
| (A) Epoxy resin | Base resin 1 | 72 | 72 | 72 | 72 |
| | Base resin 2 | — | — | — | — |
| | Curing agent | 28 | 28 | 28 | 28 |
| (B) Monofunctional | Alicyclic | 120 | 87.5 | 160 | 120 |
| acrylic monomer | Aliphatic | 120 | 87.5 | 160 | 120 |
| (C) Styrene-based elastomer | | 160 | 75 | 80 | 160 |
| (D) Hydrophobic | Hydrophobic silica | 25 | 36 | 5.2 | — |
| reinforcement | Silicone powder | — | — | — | 50 |
| powder | | | | | |
| Photo-radical polymerization initiator | | 12.0 | 8.8 | 8.8 | 8.8 |
| Incorporation ratio | Percentage (%) of (A) | 33 | 38 | 28 | 33 |
| of resins | Percentage (%) of (B) | 13 | 15 | 11 | 13 |
| | Percentage (%) of (C) | 55 | 47 | 62 | 55 |
| Evaluations of | Load (N) | 10.2 | 17.4 | 0.24 | 15.8 |
| sealant | Form stability | ⊙ | ⊙ | ◯ | ⊙ |
| composition | Conformability to irregularities | Δ | Δ | ◯ | Δ |
| Evaluations of | Storage modulus E′ (MPa) | 1.9 | 2.7 | 0.4 | 2.2 |
| sealant | Flexible properties | ◯ | ◯ | ◯ | ◯ |

<Various Tests and Evaluations on Samples>

Various tests described below were performed on the sealant compositions and the sealants of the above Samples 1 to 16, and various properties were evaluated. Measured values and evaluation results are also shown in Table 1.

The various tests described below were performed also on the sealant compositions and the sealants of the above Samples 17 to 20 in the same manner as in Samples 1 to 16, and various properties were evaluated. Measured values and evaluation results are shown in Table 2.

Measurement of Hardness of Sealant Composition:

For the sealant composition of each Sample, a load was measured when the sealant composition was compressed by 25% at a compression rate of 1 mm/min using a metal probe (made of stainless steel and plated with gold) having a cylindrical shape 10 mm in diameter and a flat end.

Evaluation of Form Stability of Sealant Composition:

A procedure was performed in which one of release films sandwiching a sealant composition was peeled off, the peeled surface was affixed to a substrate formed of a polyimide film, and then a flat pushing plate was pressed thereagainst at a pressure of 10 kPa for 5 seconds. Samples that almost maintained their shape until after being pressed were rated “◯”. Samples that, when pressed, were slightly crushed to have a slightly expanded external shape but did not flow out were rated “Δ”. Samples that were not hardened to a solid and flowed out of the release films and samples that had very poor cohesion and underwent deformation or a cohesive failure to lose their shape when the release film was peeled off were rated “×”.

Samples that almost completely maintained their shape until after being pressed were rated “⊙”.

Evaluation of Irregularity-Filling Properties (Conformability to Irregularities) of Circuit Element:

The sealant composition having a thickness of 1 mm of each Sample was affixed to a test substrate, on a flat surface of which a projection with an external shape of 1 mm×1 mm and a height of 0.5 mm was formed, and then compressed using a flat pushing plate to 0.9 mm at a pressure of 0.3 MPa and kept being pressed for 5 seconds. Samples that achieved sealing without air entrapment were rated “◯”, samples that achieved sealing but with slight air bubbles present near the bottom of the projection were rated “Δ”, and samples that did not come into close contact with an area extending from the sides to the bottom of the projection and left an air layer were rated “×”.

Measurement of Storage Modulus of Sealant:

The sealant of each Sample was cut to 5.0 mm wide×30.0 mm long (1.0 mm thick) for storage modulus E′ measurement to prepare a test piece, and its storage modulus E′ was measured using a dynamic viscoelasticity meter (“DMS6100” manufactured by Seiko Instruments, Inc.) in tensile mode at a chuck distance of 8 mm, a frequency of 1 Hz, and a measurement temperature of 23° C.

Evaluation of Flexible Properties of Sealant:

A “90° bending” test and a “150% elongation” (elongation to a length 1.5 times the initial length) test were performed as follows. First, the sealant of each Sample was cut to 50 mm wide×100 mm long (1.0 mm thick) to prepare a test piece for the 90° bending test. The test piece was bent 90° along a jig having a right angle (r of the angle=0.38 mm), and the state at this time was evaluated. Next, the sealant of each Sample was cut to 10 mm wide×50 mm long (1.0 mm thick) to prepare a test piece for the 150% elongation test. The test piece was elongated to a length of 150% at a rate of 100 mm/min with both its longitudinal ends fixed, and the state at this time was evaluated. Samples that underwent no particular change after the tests were rated “◯”, samples that slightly creased or whitened and did not completely return to their original shape but that had flexibility and did not crack or break were rated “Δ”, and samples that cracked or broke were rated “×”. The samples rated “Δ” and “◯” were evaluated as having flexible properties.

<Analysis of Evaluation Results>

The test results of the sealant compositions of Samples show that the load test results are correlated with the evaluations of form stability and conformability to irregularities of the sealant compositions; when the load is 0.19 to 3.2 N, form stability and conformability to irregularities are excellent, but when the load is 3.5 N, conformability to irregularities is poor. In terms of the percentage of the epoxy resin in the sealant composition, Sample 9, which contains about 12 mass %, has no form stability, Sample 8, which contains about 14 mass %, and Sample 3, which contains about 27 mass %, have form stability, and Sample 2, which contains about 33 mass %, has poor conformability to irregularities. This shows that the percentage of the epoxy resin in the sealant composition is preferably 15 to 27 mass % (Sample 1 to Sample 9).

Regarding the sealants, it seems that as the percentage of the epoxy resin increases, the storage modulus increases. Also, it can be seen that the storage moduli of the sealants having good flexible properties are in the range of 0.4 to 4.1 MPa.

In terms of the percentage of the (meth)acrylic ester monomer and the styrene-based elastomer, the content of the styrene-based elastomer relative to the total amount of the (meth)acrylic ester monomer and the styrene-based elastomer is 45 mass % in Sample 11 and 20 mass % in Sample 12. Also in other Samples, when the form stability and the conformability to irregularities of the sealant compositions and the flexible properties of the sealants are excellent, the content of the styrene-based elastomer is in the range of 20 to 45 mass %. Therefore, it can be seen that the content of the styrene-based elastomer is preferably in the range of 20 to 45 mass % relative to the total amount of the (meth)acrylic ester monomer and the styrene-based elastomer.

In Sample 13, in which no styrene-based elastomer was incorporated and the percentage of the epoxy resin was higher than in Sample 6, the sealant composition had both form stability and conformability to irregularities but had poor elongation properties such that tear occurred during the 150% elongation in a flexible properties test. In Sample 14, in which no styrene-based elastomer was incorporated and the percentage of the (meth)acrylic ester monomer was higher than in Sample 6, the sealant composition remained liquid and could not be provided with form stability. These results show that the styrene-based elastomer is essential to provide the form stability of the sealant composition and the flexible properties of the sealant.

In terms of the base epoxy resin, in Sample 15, in which an epoxy resin not having a flexible backbone was used, the sealant was hard and not provided with flexible properties, and in Sample 16, in which an epoxy resin having a flexible backbone and an epoxy resin not having a flexible backbone were mixed at 1:1, the evaluation of flexible properties of the sealant was “Δ”, i.e., the flexible properties were acceptable. The storage modulus was 4.1 MPa. The form stability and the conformability to irregularities of the sealant composition were satisfactory in both Sample 15 and Sample 16. These show that if the epoxy resin contains an epoxy resin not having a flexible backbone, the amount thereof is preferably not more than half the amount of an epoxy resin having a flexible backbone.

According to estimates of the incorporation amounts of the components based on the epoxy resin on the basis of the evaluation results of Samples, it is preferable to contain the (meth)acrylic ester monomer in an amount of 175 to 400 parts by mass and the styrene-based elastomer in an amount of 75 to 180 parts by mass, relative to 100 parts by mass of the epoxy resin.

Also in the test results of the sealant compositions of Samples 17 to 20, the load test results are correlated with the evaluations of form stability and conformability to irregularities of the sealant compositions; when the load is 0.24 to 17.4 N, a sealant composition excellent in form stability and conformability to irregularities is provided.

In a comparison of Sample 18 and Sample 3, the load was 3.2 N in Sample 3, whereas in Sample 18, in which a hydrophobic reinforcement powder was added, the load increased to 17.4 N. However, despite the increase in load, conformability to irregularities was “Δ”, i.e., no more than slightly impaired. In contrast to this result, in Sample 2 and Sample 1, in which the load increased as a result of increasing the percentage of the epoxy resin, conformability to irregularities was “×” although the load was less than 17.4 N. This shows that conformability to irregularities is impaired when handling properties are improved by increasing hardness through the matrix epoxy resin, whereas conformability to irregularities is unlikely to be impaired when handling properties are improved by increasing hardness through the addition of a hydrophobic reinforcement powder.

In a comparison of Sample 19 and Sample 12, the load was 0.19 N in Sample 12, whereas in Sample 19, in which a hydrophobic reinforcement powder was added, the load increased to 0.24 N. As a result, in Sample 19, conformability to irregularities is comparable to that in Sample 12, while form stability can be further improved.

In Sample 20, a hydrophobic reinforcement powder having a large particle size was used, but also in this case, it can be seen that form stability can be increased although there is almost no decrease in conformability to irregularities.

1. A sealant composition capable of protecting an adherend such as an electronic device from moisture, foreign matter, and the like by covering the adherend, the sealant composition comprising, as essential components, a cured epoxy resin having a flexible backbone, a monofunctional (meth)acrylic ester monomer, a photo-radical polymerization initiator, and a styrene-based elastomer, wherein the monofunctional (meth)acrylic ester monomer is curable by irradiation with light, and
the sealant composition has form stability and also has a flexibility such that a load measured when the sealant composition having a thickness of 1 mm is compressed by 25% with a cylindrical probe having a bottom end with a diameter of 10 mm is 0.19 to 3.2 N.

2. The sealant composition according to claim 1, further comprising a hydrophobic reinforcement powder in an amount of 5 to 50 parts by mass relative to 100 parts by mass of the epoxy resin,
wherein the sealant composition has form stability and also has a flexibility such that a load measured when the sealant composition having a thickness of 1 mm is compressed by 25% with a cylindrical probe having a bottom end with a diameter of 10 mm is 0.24 to 17.4 N.

3. The sealant composition according to claim 1, wherein the monofunctional (meth)acrylic ester monomer is constituted by a monofunctional alicyclic (meth)acrylic ester monomer and a monofunctional aliphatic (meth)acrylic ester monomer.

4. The sealant composition according to claim 1, wherein the monofunctional (meth)acrylic ester monomer is contained in an amount of 175 to 400 parts by mass relative to 100 parts by mass of the cured epoxy resin.

5. The sealant composition according to claim 1, wherein the styrene-based elastomer is contained in an amount of 75 to 200 parts by mass relative to 100 parts by mass of the cured epoxy resin.

6. The sealant composition according to claim 1, wherein a weight percentage of the styrene-based elastomer relative to a total weight of the styrene-based elastomer and the monofunctional (meth)acrylic ester monomer is 20 to 45 mass %.

7. The sealant composition according to claim 1, wherein the styrene-based elastomer is a styrene-isobutylene-styrene block copolymer.

8. The sealant composition according to claim 1, wherein the cured epoxy resin having a flexible backbone is a cured epoxy resin that has two or more epoxy groups in one molecule and that includes, as a part of the molecule, at least one flexible backbone selected from a polyethylene glycol backbone, a polypropylene glycol backbone, a polyether backbone, a urethane backbone, a polybutadiene backbone, and a nitrile rubber backbone.

9. A sealant comprising, as essential components, a cured epoxy resin having a flexible backbone, an acrylic resin, and a styrene-based elastomer, the acrylic resin being obtained by curing the monofunctional (meth)acrylic ester monomer in the sealant composition according to claim 1, wherein the sealant has desired flexible properties.
